(19) United States
(12) Patent Application Publication
(10) Pub. No.: US 2007/0052056 A1
(43) Pub. Date: Mar. 8, 2007

(54) SOLID-STATE IMAGING DEVICE AND METHOD OF MANUFACTURING SAME

(75) Inventors: Takashi Doi, Kanagawa-ken (JP); Toshihiko Kitamura, Kanagawa-ken (JP); Takayuki Sakai, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/470,118

(22) Filed: Sep. 5, 2006

(30) Foreign Application Priority Data
Sep. 5, 2005 (JP) 2005-257085
Jul. 18, 2006 (JP) 2006-195075

(51) Int. Cl. H01L 31/06

(52) U.S. Cl. 257/462

(57) ABSTRACT

A solid-state imaging device includes: a semiconductor substrate; and a signal processing section provided on a backside of the semiconductor substrate. The semiconductor substrate has; a first impurity region of a first conductivity type, the first impurity region storing a signal charge produced through photoelectric conversion by a photoelectric conversion section formed in a surface portion of the semiconductor substrate; a second impurity region of the first conductivity type formed below the first impurity region; and a first gate electrode penetrating the semiconductor substrate in a thickness direction of the semiconductor substrate, the first gate electrode transferring the signal charge stored in the first impurity region to the second impurity region. The signal processing section receives the signal charge transferred to the second impurity region.

### CROSS-REFERENCE TO RELATED APPLICATIONS

This application is based upon and claims the benefit of priority from the prior Japanese Patent Application No. 2005-257085, filed on Sep. 5, 2005, and the prior Japanese Patent Application No. 2006-195075, filed on Jul. 18, 2006; the entire contents of which are incorporated herein by reference.

### BACKGROUND OF THE INVENTION

1. Field of the Invention

This invention relates to a solid-state imaging device and a method of manufacturing the same.

2. Background Art

Recently, in solid-state imaging devices such as CMOS image sensors, the pixel size has been significantly reduced to meet the demands for downsizing the device and increasing the number of pixels. A solid-state imaging device of today has a structure in which color filters, microlenses, and interconnects such as vertical signal lines are formed on photodiodes.

However, as the pixel size becomes even smaller and the interconnects are further multilayered, the distance from the sensor surface to the photodiodes is increased in the structure as described above, and obliquely incident light will suffer interference from the interconnects (shading effect). This prevents the light from reaching the photodiode and decreases the incidence efficiency of light incident on the photodiode.

In a disclosed technique (e.g., JP 2005-038908A), a gate electrode is buried in an element isolation layer between pixels. A signal charge stored in the N-type impurity region constituting the photodiode is transferred by this gate electrode to an N-type floating diffusion region formed on the N-type impurity region. However, even in this technique, it is difficult to solve the above-described problem because interconnects such as vertical signal lines are formed on the photodiodes.

### SUMMARY OF THE INVENTION

According to an aspect of the invention, there is provided a solid-state imaging device comprising: a semiconductor substrate having; a first impurity region of a first conductivity type, the first impurity region storing a signal charge produced through photoelectric conversion by a photoelectric conversion section formed in a surface portion of the semiconductor substrate; a second impurity region of the first conductivity type formed below the first impurity region; and a first gate electrode penetrating the semiconductor substrate in a thickness direction of the semiconductor substrate, the first gate electrode transferring the signal charge stored in the first impurity region to the second impurity region; and a signal processing section provided on a backside of the semiconductor substrate, the signal processing section receiving the signal charge transferred to the second impurity region.

According to other aspect of the invention, there is provided a solid-state imaging device comprising: a semiconductor substrate having; a first impurity region of a first conductivity type, the first impurity region storing a signal charge produced through photoelectric conversion by a photoelectric conversion section formed in a surface portion of the semiconductor substrate; a second impurity region of the first conductivity type formed in the semiconductor substrate at a part lower than the first impurity region; a first gate electrode penetrating the semiconductor substrate in a thickness direction of the semiconductor substrate, the first gate electrode transferring the signal charge stored in the first impurity region to the second impurity region; and an overflow drain unit of the first conductivity type being in contact with the first impurity region, the overflow drain unit extending to a backside of the semiconductor substrate; and a signal processing section provided on the backside of the semiconductor substrate, the signal processing section receiving the signal charge transferred to the second impurity region.

According to other aspect of the invention, there is provided a method of manufacturing a solid-state imaging device, comprising: forming a first impurity region of a first conductivity type, the first impurity region storing a signal charge produced through photoelectric conversion by a photoelectric conversion section in a surface portion of a semiconductor substrate; forming a trench, the trench penetrating the semiconductor substrate; forming a second impurity region of the first conductivity type below the first impurity region in the semiconductor substrate by introducing impurities of the first conductivity type on at least one side face of an inner wall of the trench; forming a gate electrode by burying a conductive material in the trench via an insulating film; and forming a signal processing section on the backside of the semiconductor substrate.

### BRIEF DESCRIPTION OF THE DRAWINGS

FIG. 1 is a schematic vertical cross section of a CMOS image sensor 1 according to a first embodiment of the invention.

FIG. 2 is a schematic plan view of the CMOS image sensor 1 according to the first embodiment of the invention where microlenses and color filters are omitted.

FIG. 3 is a schematic plan view of another CMOS image sensor 1 according to the first embodiment of the invention where microlenses and color filters are omitted.

FIG. 4 is a schematic circuit diagram of a CMOS image sensor 1 according to the first embodiment of the invention.

FIGS. 5A to 8C schematically show a process of manufacturing a CMOS image sensor 1 according to the first embodiment of the invention.

FIG. 9 is a schematic plan view of a CMOS image sensor 101 according to a second embodiment of the invention where microlenses and color filters are omitted.

FIG. 10 is a vertical cross section along the line A-A of the CMOS image sensor 101 shown in FIG. 9.

FIG. 11 is a vertical cross section along the line B-B of the CMOS image sensor 101 shown in FIG. 9.

FIGS. 12A to 21B schematically show a process of manufacturing a CMOS image sensor 101 according to the second embodiment of the invention.

### DETAILED DESCRIPTION OF THE INVENTION

Embodiments of the invention will now be described with reference to the drawings. In the embodiments, by way of illustration, a CMOS image sensor is used as an example of the solid-state imaging device.

### First Embodiment

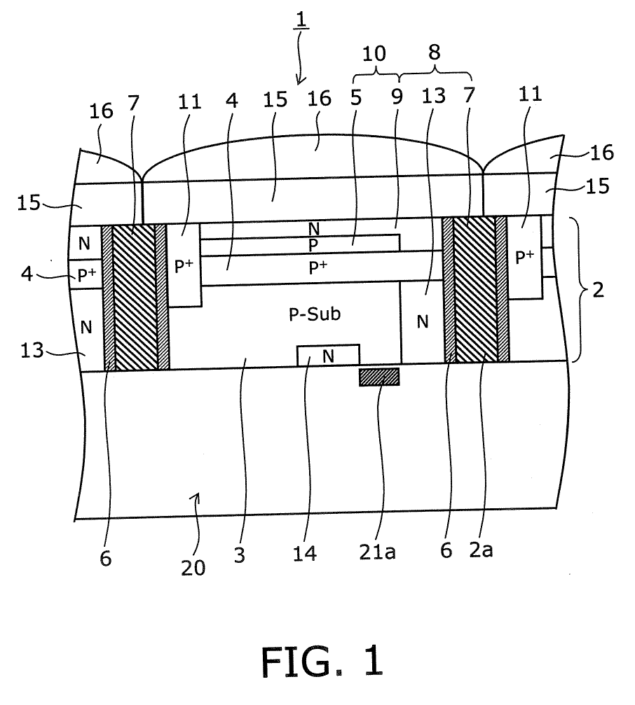

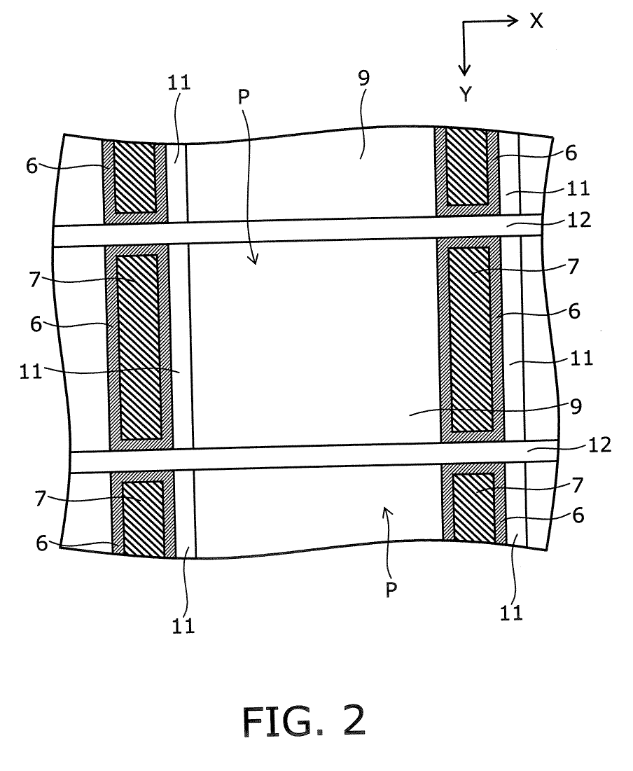

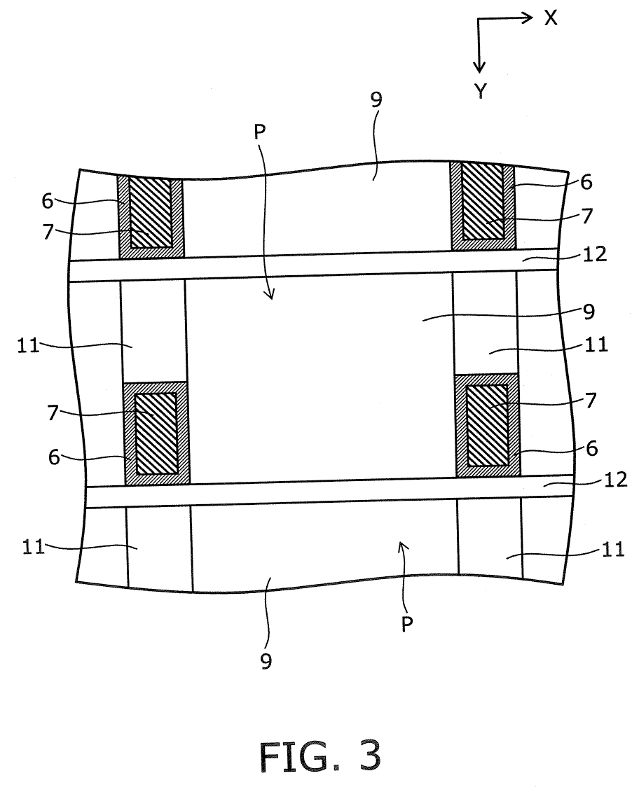

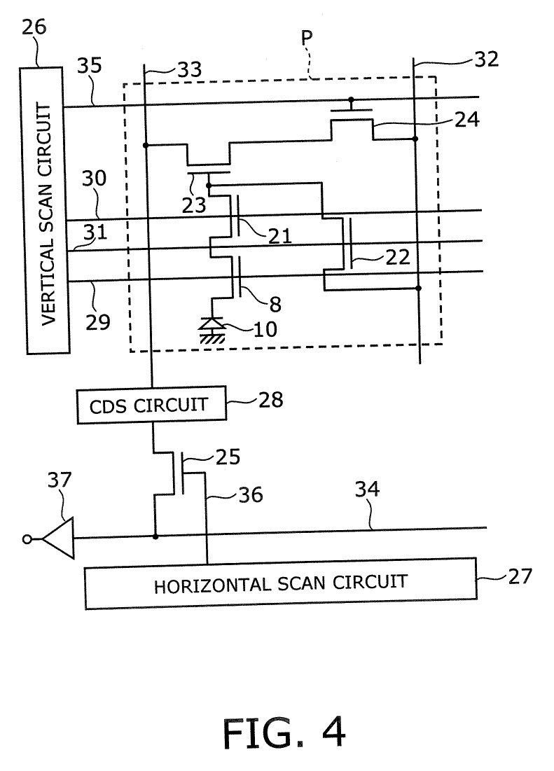

FIG. 1 is a schematic vertical cross section of a CMOS image sensor according to a first embodiment of the invention. FIG. 2 is a schematic plan view of the CMOS image sensor according to the first embodiment of the invention where microlenses and color filters are omitted. FIG. 3 is a schematic plan view of another CMOS image sensor according to the first embodiment of the invention where microlenses and color filters are omitted. FIG. 4 is a schematic circuit diagram of a CMOS image sensor according to the first embodiment of the invention.

As shown in FIGS. 1 and 2, the CMOS image sensor 1 has a semiconductor substrate 2 having a thickness of about 100 μm. The semiconductor substrate 2 illustratively includes a P-type Si substrate (a fifth impurity region) 3, a P⁺-type epitaxial layer (a fourth impurity region) 4 formed on the P-type Si substrate 3 and having a higher impurity concentration than the P-type Si substrate 3, and a P-type epitaxial layer (a third impurity region) 5 formed on the P⁺-type epitaxial layer 4 and having an impurity concentration nearly comparable to that of the P-type Si substrate 3.

Because of the multilayer structure as described above, the thickness of the semiconductor substrate 2 can be varied as appropriate on the order of several micrometers to several hundreds of micrometers depending on the thickness of the constituent layers.

The P-type Si substrate 3 and the P-type epitaxial layer 5 have an impurity concentration of about 1.0×10¹⁸/cm³, and the P⁺-type epitaxial layer 4 has an impurity concentration of about 1.0×10²⁰/cm³. The total thickness of the P⁺-type epitaxial layer 4 and the P-type epitaxial layer 5 is about 5 to 10 μm.

The semiconductor substrate 2 has trenches 2a that penetrate the semiconductor substrate 2 in the thickness direction. The trench 2a has a width of about 0.8 μm.

A gate insulating film 6 is formed on the inner wall of the trench 2a, and a gate electrode (a first gate electrode) 7 is formed inside the gate insulating film 6. In response to application of voltage, the gate electrode 7 serves to read a signal charge, which has been stored in an N-type impurity region 9 described later, and to transfer the signal charge to a charge storage region 13 described later. That is, this portion constitutes a transfer transistor 8, where the source is the N-type impurity region (a first impurity region) 9, the gate is the gate electrode 7, and the drain is the charge storage region (a second impurity region) 13. Through a read control line 29 described later, a common voltage is applied to the gate electrodes 7 adjacent to each other in the width direction of the trench 2a (horizontally across page in FIG. 2).

An N-type impurity region 9 is formed as a first impurity region on the P-type epitaxial layer 5, which is the surface layer of the semiconductor substrate 2. One of the side faces of the N-type impurity region 9 is adjacent to the gate electrode 7 via the gate insulating film 6. The P-type epitaxial layer 5 and the N-type impurity region 9 constitute a photodiode 10, which is a photoelectric conversion section for converting incident light into a signal charge. The signal charge produced by photoelectric conversion is stored in the N-type impurity region 9.

The one side portion of the N-type impurity region 9 adjacent to the gate electrode 7 is formed deeper than the other portion of the N-type impurity region 9. The bottom of this side portion is adjacent to the P⁺-type epitaxial layer 4. The other side face of the N-type impurity region 9 is adjacent to a channel stopper region (an eighth impurity region) 11, which is provided for device isolation between the pixels P.

The channel stopper region 11 is a P⁺-type impurity region and formed in the upper portion of the P-type epitaxial layer 5, the P⁺-type epitaxial layer 4, and the P-type Si substrate 3. The side face of the channel stopper region 11 is adjacent to the gate insulating film 6 of the neighboring pixel P. That is, the channel stopper region 11 is juxtaposed with the gate insulating film 6 in the width direction of the trench 2a (horizontally across page in FIG. 2).

As shown in FIG. 3, the channel stopper region 11 may be formed in the semiconductor substrate 2 so that both side faces are adjacent to the N-type impurity regions 9 of the neighboring pixels P. That is, the channel stopper region 11 is juxtaposed with the gate insulating film 6 in the longitudinal direction of the trench 2a (vertically across page in FIG. 2). In this case, device isolation between the pixels P is partly provided by the gate insulating film 6, and for the rest is provided by the channel stopper region 11.

In FIGS. 2 and 3, device isolation between the pixels P in the width direction of the trench 2a is provided by the gate insulating film 6 and the channel stopper region 11. On the other hand, device isolation between the pixels P in the vertical direction is provided by a channel stopper region (a seventh impurity region) 12, which is a P⁺-type impurity region extending along a direction X as shown in FIGS. 2 and 3, and is formed in the semiconductor substrate 2 in this portion.

Below the N-type impurity region 9 and in the P-type Si substrate 3, a charge storage region 13 is formed as a second impurity region to which the signal charge stored in the N-type impurity region 9 is transferred. The charge storage region 13 is an N-type impurity region. One side face thereof is adjacent to the gate electrode 7 via the gate insulating film 6, and the upper face is adjacent to the P⁺-type epitaxial layer 4.

At the bottom of the P-type Si substrate 3 is formed a floating diffusion region (a sixth impurity region) 14 (this region is hereinafter referred to as “FD region”), which is a portion of a signal processing section 20 described later and to which the signal charge stored in the charge storage region 13 is transferred. The FD region 14 is an N-type impurity region. When the signal charge stored in the charge storage region 13 is transferred to the FD region 14, a voltage is applied to a gate electrode (a second gate electrode) 21a of a transfer transistor 21 described later.

On the frontside of the semiconductor substrate 2, a color filter 15 is formed. On the color filter 15 is formed a microlens 16, which serves as a lens for focusing light and guiding the light to the photodiode 10.

On the backside of the semiconductor substrate 2 (backside of the P-type Si substrate 3) is formed a signal processing section 20 to which the signal charge transferred to the charge storage region 13 is inputted. As shown in FIG. 4, the signal processing section 20 includes a transfer transistor 21, a reset transistor 22, an amplification transistor 23, a vertical selection transistor 24, a horizontal selection transistor 25, a vertical scan circuit 26, a horizontal scan circuit 27, a CDS circuit (correlated double sampling circuit) 28, read control lines 29 and 30, a reset control line 31, a drain line 32, a vertical signal line 33, a horizontal signal line 34, a vertical selection control line 35, a horizontal selection control line 36, and an amplifier 37.

The transfer transistor 21 transfers the signal charge stored in the charge storage region 13 to the FD region 14. The source of the transfer transistor 21 is the charge storage region 13, the gate is the gate electrode 21a, and the drain is the FD region 14. The gate electrode 21a is electrically connected to the read control line 30. On the other hand, the read control line 29 is electrically connected to the gate electrode 7 of the transfer transistor 8.

The reset transistor 22 periodically resets the signal charge stored in the FD region 14. The source, gate, and drain of the reset transistor 22 are electrically connected to the FD region 14, the reset control line 31, and the drain line 32, respectively.

The amplification transistor 23 detects voltage variation of the FD region 14 and converts it into a current signal. The drain, gate, and source of the amplification transistor 23 are electrically connected to the source of the vertical selection transistor 24, to the FD region 14, and to the vertical signal line 33, respectively.

The vertical selection transistor 24 and the horizontal selection transistor 25 serve to select a specific pixel column. The drain and gate of the vertical selection transistor 24 are electrically connected to the drain line 32 and the vertical selection control line 35, respectively. The drain, gate, and source of the horizontal selection transistor 25 are electrically connected to the vertical signal line 33, the horizontal selection control line 36, and the horizontal signal line 34, respectively.

Each pixel P includes a photodiode 10, transfer transistors 8 and 21, a reset transistor 22, an amplification transistor 23, and a vertical selection transistor 24.

The vertical scan circuit 26 applies voltage to the read control line 29 and the like to control the transfer transistor 8 and the like. The horizontal scan circuit 27 applies voltage to the horizontal selection control line 36 to control the horizontal selection transistor 25.

The CDS circuit 28 serves to remove fixed pattern noise due to the fluctuated threshold voltage of the transfer transistor 8 and the like included in the pixel P, and is interposed in the vertical signal line 33. The CDS circuit 28 is illustratively composed of two capacitors (not shown), a sampling transistor (not shown), and a clamp transistor (not shown).

The CMOS image sensor 1 is operated as follows. First, a voltage is applied to the vertical selection control line 35 by the vertical scan circuit 26, and the vertical selection transistor 24 is turned on. Thus a specific pixel column is selected.

Next, in this state, a voltage is applied to the read control line 29 by the vertical scan circuit 26, and the transfer transistor 8 is turned on. Thus the signal charge stored in the N-type impurity region 9 is transferred to the charge storage region 13.

Then, when the transfer transistor 8 is turned off, a voltage is applied to the read control line 30 by the vertical scan circuit 26, and the transfer transistor 21 is turned on. Thus the signal charge stored in the charge storage region 13 is transferred to the FD region 14.

This operation of transferring the signal charge causes voltage variation in the FD region 14. In response to the voltage variation, a current signal is outputted from the amplification transistor 23 to the vertical signal line 33. On the other hand, a voltage is applied to the reset control line 31 by the vertical scan circuit 26, and the reset transistor 22 is turned on. Thus the voltage of the FD region 14 is reset.

The current signal outputted to the vertical signal line 33 is outputted to the horizontal signal line 34 via the CDS circuit 28 and via the horizontal selection transistor 25 which is selected by the horizontal scan circuit 27 to be turned on. Then the current signal is amplified by the amplifier 37 and outputted to the outside.

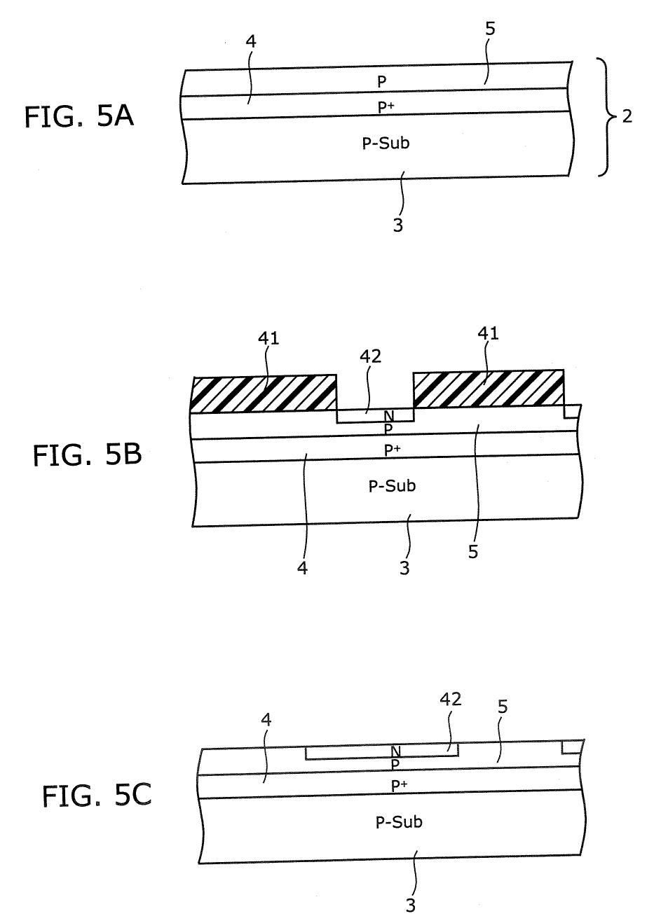

The CMOS image sensor 1 can be fabricated in the following manner. FIGS. 5A to 8C schematically show a process of manufacturing a CMOS image sensor 1 according to the first embodiment of the invention.

First, as shown in FIG. 5A, on a P-type Si substrate 3 having a thickness of several hundreds of micrometers, a P⁺-type epitaxial layer 4 is formed, and then a P-type epitaxial layer 5 is formed. Thus a semiconductor substrate 2 is formed.

After the semiconductor substrate 2 is formed, as shown in FIG. 5B, a resist pattern 41 is formed by photolithography. Then the resist pattern 41 is used as a mask to inject N-type impurities such as phosphorus or arsenic into the P-type epitaxial layer 5 by ion implantation. Thus an N-type impurity region 42, which is to be part of the N-type impurity region 9, is formed in the P-type epitaxial layer 5.

After the N-type impurity region 42 is formed, the resist pattern 41 is removed. Then, as shown in FIG. 5C, N-type impurities constituting the N-type impurity region 42 are diffused by annealing. Thus the N-type impurity region 42 has a depth of about 1 to 2 μm.

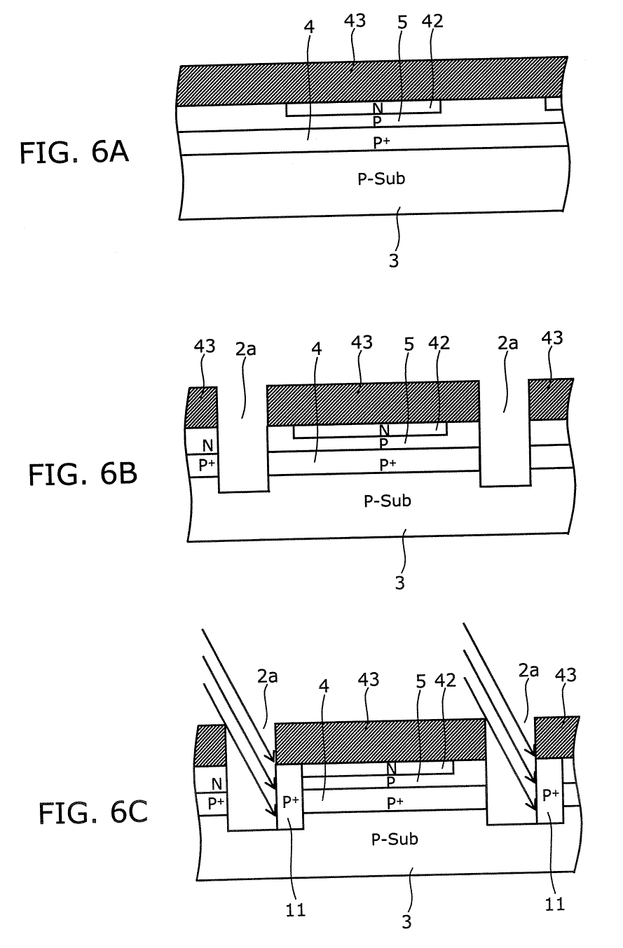

After the N-type impurity region 42 is formed, as shown in FIG. 6A, an SiO₂ film 43 having a thickness of about 3 μm is formed on the P-type epitaxial layer 5. Then, the backside of the P-type Si substrate 3 is polished so that the semiconductor substrate 2 has a thickness of about 100 μm. Alternatively, a thin P-type Si substrate 3 may be prepared so that the semiconductor substrate 2 has a thickness of about 100 μm, and a P⁺-type epitaxial layer 4 and a P-type epitaxial layer 5 may be formed on the P-type Si substrate 3. This can save time and effort to polish the backside of the P-type Si substrate 3.

After the backside of the P-type Si substrate 3 is polished, a resist pattern (not shown) is formed on the SiO₂ film 43 by photolithography. Then the resist pattern is used as a mask to etch the SiO₂ film 43 by reactive ion etching (RIE). Then the resist pattern is removed. Next, as shown in FIG. 6B, the patterned SiO₂ film 43 is used as a mask to etch the semiconductor substrate 2 in the thickness direction by reactive ion etching or wet etching, thereby forming trenches 2a. Here, etching is controlled so as to stop in the upper portion of the P-type Si substrate 3.

After etching is conducted to the upper portion of the P-type Si substrate 3, as shown in FIG. 6C, P-type impurities such as boron are injected into an inner wall on one side of the trench 2a by oblique ion implantation to form a channel stopper region 11.

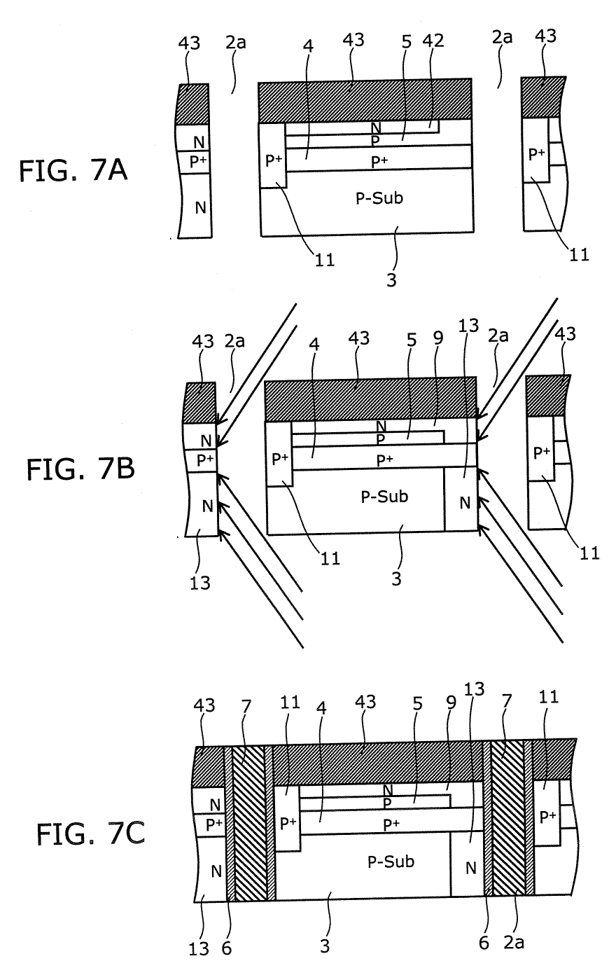

After the channel stopper region 11 is formed, as shown in FIG. 7A, the SiO₂ film 43 is used as a mask to etch the P-type Si substrate 3 by reactive ion etching or wet etching, thereby allowing the trenches 2a to penetrate therethrough.

After penetration of the trenches 2a, as shown in FIG. 7B, oblique ion implantation is used to inject N-type impurities into the inner wall of the trench 2a opposed to the inner wall where the channel stopper region 11 is formed. Thus, in the P-type epitaxial layer 5 is formed an N-type impurity region 9, where one of its side faces is adjacent to the trench 2a and the lower face of its end portion is adjacent to the P⁺-type epitaxial layer 4. Simultaneously, in the P-type Si substrate 3 is formed a charge storage region 13, where one of its side faces is adjacent to the trench 2a and its upper face is adjacent to the P⁺-type epitaxial layer 4.

Then, P-type impurities constituting the channel stopper region 11 and N-type impurities constituting the N-type impurity region 9 and the charge storage region 13 are diffused by annealing. While the N-type impurity region 9 and the charge storage region 13 are formed by injecting N-type impurities from both of the frontside and backside of the semiconductor substrate 2 in FIG. 7B, the N-type impurity region 9 and the charge storage region 13 can also be formed by injecting N-type impurities from only one of the frontside and backside of the semiconductor substrate 2.

Next, the inner wall of the trench 2a is thermally oxidized to form a gate insulating film 6 as shown in FIG. 7C. Subsequently, a conductive material such as poly-Si is buried inside the gate insulating film 6 to form a gate electrode 7. After the gate electrode 7 is formed, the frontside and backside of the semiconductor substrate 2 are polished by chemical mechanical polishing (CMP). In this process, the SiO₂ film 43 is removed.

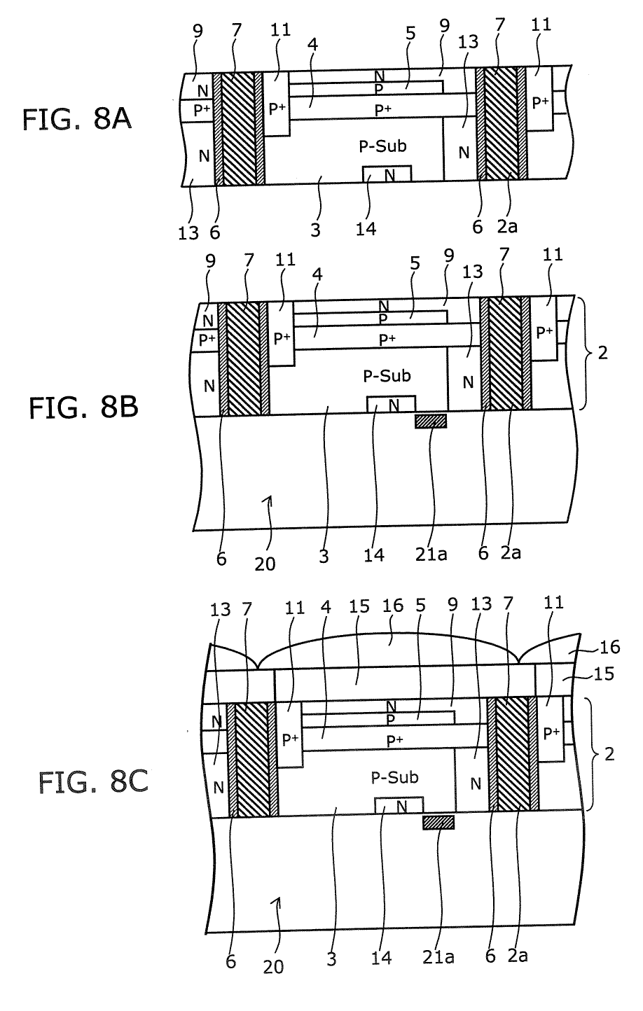

After the frontside and backside of the semiconductor substrate 2 are polished, a resist pattern (not shown) is formed on the backside of the semiconductor substrate 2 by photolithography. The resist pattern is used as a mask to inject N-type impurities into the bottom of the P-type Si substrate 3 by ion implantation, thereby forming an FD region 14 at the bottom of the P-type Si substrate 3 as shown in FIG. 8A. Subsequently, N-type impurities constituting the FD region 14 are diffused by annealing.

After the FD region 14 is formed, the resist pattern is removed. Subsequently, as shown in FIG. 8B, a signal processing section 20 is formed on the backside of the P-type Si substrate 3. In view of efficiency, it is preferable that the gate electrode 21a be formed from the same material (e.g., aluminum) and in the same process as the interconnect pad formed in the signal processing section 20. However, the gate electrode 21a may be formed by using poly-Si in a separate process from that for the interconnect pad.

Finally, as shown in FIG. 8C, a color filter 15 is formed on the N-type impurity region 9 by photolithography, and a microlens 16 is formed on the color filter 15. Thus the CMOS image sensor 1 shown in FIG. 1 is fabricated.

In this embodiment, because the signal processing section 20 is formed on the backside of the semiconductor substrate 2 as shown in FIG. 1, light incident on the photodiode 10 formed in the semiconductor substrate 2 suffers no interference from interconnects and the like of the signal processing section 20. Thus, even the light obliquely incident on the photodiode 10 can reach the photodiode 10. As a result, the incidence efficiency of light incident on the photodiode 10 can be improved.

In the case of forming the signal processing section 20 on the backside of the semiconductor substrate 2, it is necessary to transfer the signal charge from the N-type impurity region 9 to the signal processing section 20. In this embodiment, because a charge storage region 13 is formed below the N-type impurity region 9 and a gate electrode 7 is formed in the semiconductor substrate 2, the signal charge stored in the N-type impurity region 9 can be transferred to the signal processing section 20.

In this embodiment, because the signal processing section 20 is formed on the backside of the semiconductor substrate 2, the region of the photodiode 10 in the plane of the CMOS image sensor 1 can be increased. Thus the incidence efficiency of light incident on the photodiode 10 can be further improved. In addition, because the region of the photodiode 10 can be increased (ineffective region can be reduced), the microlens 16 can be omitted on the color filter 15.

In this embodiment, in the case as shown in FIG. 3 where a channel stopper region 11 is juxtaposed with the gate insulating film 6 in the longitudinal direction of the trench 2a for device isolation between the pixels P, the mechanical strength of the semiconductor substrate 2 can be prevented from decreasing. More specifically, the gate insulating film 6 and the gate electrode 7 are formed in the trench 2a that penetrates the semiconductor substrate 2. However, because of the very small distance between the pixels P in the longitudinal direction of the trench 2a, the mechanical strength of the semiconductor substrate 2 may be decreased if the trenches 2a are juxtaposed in the longitudinal direction of the trench 2a.

In contrast, when a channel stopper region 11 is juxtaposed with the gate insulating film 6 in the longitudinal direction of the trench 2a for device isolation between the pixels P, the proportion of the trenches 2a occupying in the semiconductor substrate 2 is decreased. Thus the mechanical strength of the semiconductor substrate 2 can be prevented from decreasing.

The invention is not limited to the embodiment described above. The embodiment can be modified as appropriate in its structure and material and in the placement of its various members without departing from the spirit of the invention. For example, while a CMOS image sensor 1 is described in the above embodiment as an example of the solid-state imaging device, it may be a CCD image sensor.

In the embodiment described above, the first impurity region is the N-type impurity region 9. However, the first impurity region may be different from the N-type impurity region 9. That is, the first impurity region may be an N-type impurity region to which the signal charge is transferred directly or indirectly from the N-type impurity region 9.

In the embodiment described above, the second impurity region is the charge storage region 13. However, if the gate electrode 7 is used to transfer the signal charge from the N-type impurity region 9 to the FD region 14 without the intermediary of the charge storage region 13, the second impurity region can be the FD region 14.

### Second Embodiment

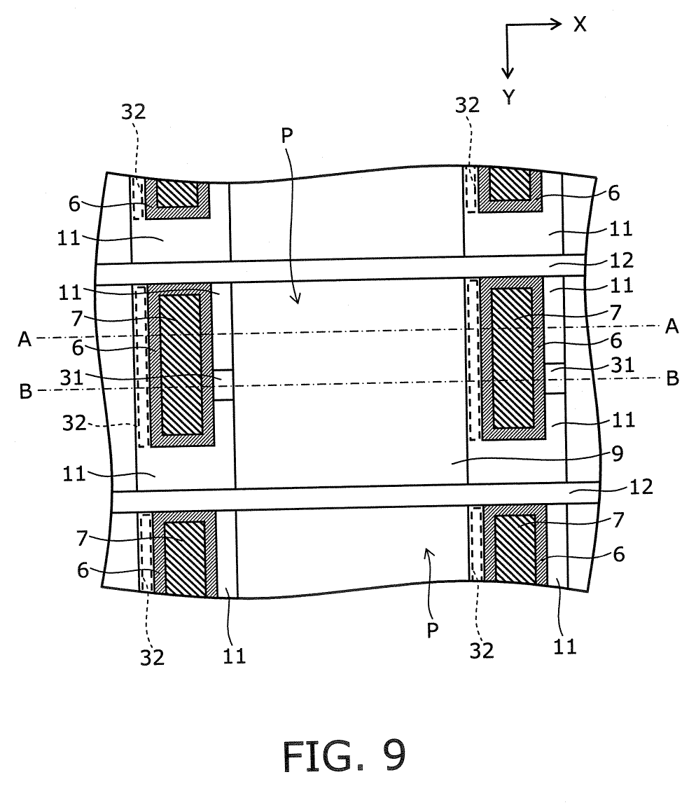

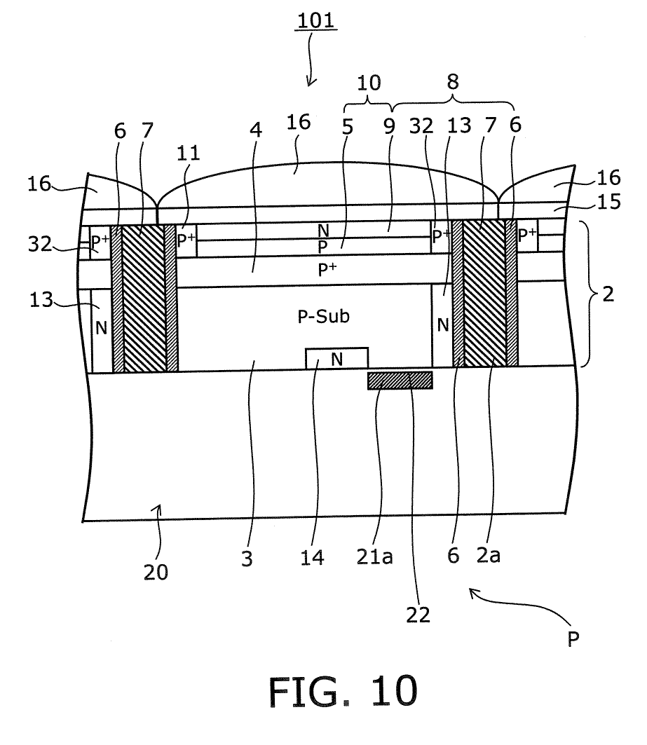

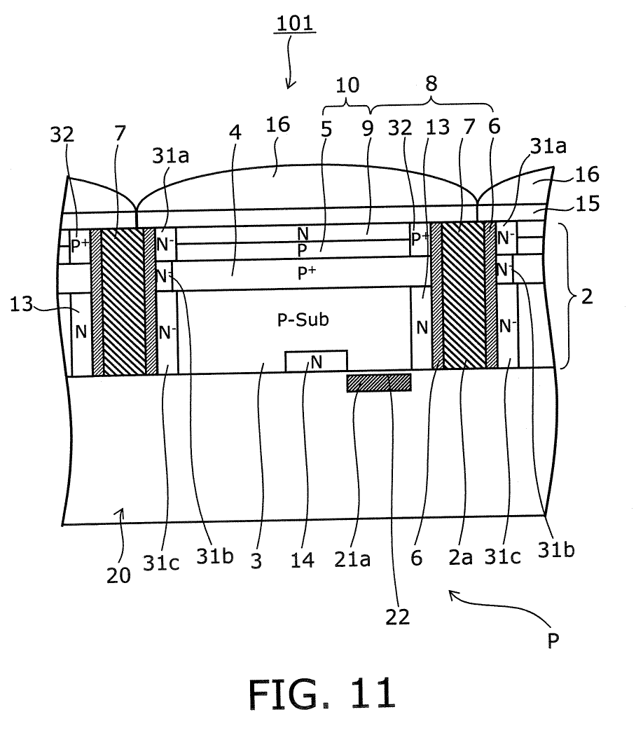

FIGS. 9 to 11 are schematic configuration views of a CMOS image sensor 101 according to a second embodiment of the invention. FIG. 9 is a schematic plan view of a CMOS image sensor according to the second embodiment of the invention where microlenses and color filters are omitted. FIGS. 10 and 11 are vertical cross sections along the lines A-A and B-B, respectively, of the CMOS image sensor 101 shown in FIG. 9. The schematic circuit diagram of the CMOS image sensor 101 according to this embodiment is not shown herein, because it is similar to that in FIG. 4.

This embodiment differs from the first embodiment described above in that an overflow drain unit 31 is provided generally at the center of the channel stopper region 11 serving for device isolation between adjacent pixels P, and in that a P-type impurity layer 32 is provided opposite to the channel stopper region 11 and the overflow drain unit 31. The rest of the configuration is the same as the previous embodiment. The same elements as those in the previous embodiment are marked with the same reference numerals.

As shown in FIGS. 10 and 11, the CMOS image sensor 101 has a semiconductor substrate 2 having a thickness of about 100 μm. As with the first embodiment, the semiconductor substrate 2 is illustratively composed of a P-type Si substrate (a fifth impurity region) 3, a P⁺-type epitaxial layer (a fourth impurity region) 4 formed on the P-type Si substrate 3 and having a higher impurity concentration than the P-type Si substrate 3, and a P-type epitaxial layer (a third impurity region) 5 formed on the P⁺-type epitaxial layer 4 and having an impurity concentration nearly comparable to that of the P-type Si substrate 3.

Because of the multilayer structure as described above, the thickness of the semiconductor substrate 2 can be varied as appropriate on the order of several micrometers to several hundreds of micrometers depending on the thickness of the constituent layers.

The P-type Si substrate 3 and the P-type epitaxial layer 5 illustratively have an impurity concentration of about 1.0×10¹⁸/cm³, and the P⁺-type epitaxial layer 4 illustratively has an impurity concentration of about 1.0×10²⁰/cm³. The total thickness of the P⁺-type epitaxial layer 4 and the P-type epitaxial layer 5 is illustratively about 5 to 10 μm.

The semiconductor substrate 2 has trenches 2a that penetrate the semiconductor substrate 2 in the thickness direction. The trench 2a illustratively has a width of about 0.8 μm.

A gate insulating film 6 is formed on the inner wall of the trench 2a, and a gate electrode (a first gate electrode) 7 is formed inside the gate insulating film 6. As with the previous embodiment, in response to application of voltage, the gate electrode 7 serves to read a signal charge, which has been stored in an N-type impurity region 9, and to transfer the signal charge to a charge storage region 13. That is, this portion constitutes a transfer transistor 8, where the source is the N-type impurity region 9, the gate is the gate electrode 7, and the drain is the charge storage region 13. Through the read control line 29 described in the previous embodiment, a common voltage is applied to the gate electrodes 7 adjacent to each other in the width direction of the trench 2a (horizontally across page in FIGS. 10 and 11).

An N-type impurity region 9 is formed as a first impurity region on the P-type epitaxial layer 5, which is the surface layer of the semiconductor substrate 2. One of the side faces of the N-type impurity region 9 is adjacent to the gate electrode 7 via the P-type impurity region 32 and the gate insulating film 6. The P-type epitaxial layer 5 and the N-type impurity region 9 constitute a photodiode 10, which is a photoelectric conversion section for converting incident light into a signal charge. The signal charge produced by photoelectric conversion is stored in the N-type impurity region 9.

The bottom of the P-type impurity region 32 is deeper than the bottom of the N-type impurity region 9 and adjacent to the upper face of the P⁺-type epitaxial layer 4. As shown in FIG. 10, one of the side faces of the N-type impurity region 9 is adjacent to a channel stopper region (a eighth impurity region) 11, which is provided for device isolation between the pixels P.

The channel stopper region 11 is a P⁺-type impurity region and formed in the upper portion of the P-type epitaxial layer 5, the P⁺-type epitaxial layer 4, and the P-type Si substrate 3. The side face of the channel stopper region 11 is adjacent to the gate insulating film 6 of the neighboring pixel P. That is, the channel stopper region 11 is juxtaposed with the gate insulating film 6 in the width direction of the trench 2a (horizontally across page in FIG. 10).

The channel stopper region 11 is juxtaposed with the gate insulating film 6 in the longitudinal direction of the trench 2a (vertically across page in FIG. 9). In this case, device isolation between the pixels P is partly provided by the gate insulating film 6, and for the rest is provided by the channel stopper region 11.

In FIGS. 9 to 11, device isolation between the pixels P in the width direction of the trench 2a is provided by the gate insulating film 6 and the channel stopper region 11. On the other hand, device isolation between the pixels P in the vertical direction (perpendicular to the page) is provided by a channel stopper region 12, which is a P⁺-type impurity region formed in the semiconductor substrate 2 in this portion, as shown in FIG. 9.

Below the N-type impurity region 9 and in the P-type Si substrate 3, a charge storage region 13 is formed as a second impurity region to which the signal charge stored in the N-type impurity region 9 is transferred. The charge storage region 13 is an N-type impurity region. One of its side faces is adjacent to the gate electrode 7 via the gate insulating film 6, and the upper face of the charge storage region 13 is adjacent to the bottom of the P⁺-type epitaxial layer 4.

As described in the previous embodiment, at the bottom of the P-type Si substrate 3 is formed an FD region (a sixth impurity region) 14, which is a portion of a signal processing section 20 and to which the signal charge stored in the charge storage region 13 is transferred. The FD region 14 is an N-type impurity region. As described in the previous embodiment, when the signal charge stored in the charge storage region 13 is transferred to the FD region 14, a voltage is applied to a gate electrode (a second gate electrode) 21a of a transfer transistor 21.

On the other hand, as shown in FIG. 11, the overflow drain unit 31 is provided in a side face of the pixel P, the side face being opposed in the width direction (horizontally across page in FIG. 11) to the side face of the trench 2a where the transfer transistor 8 is provided. The overflow drain unit 31 is formed in the vertical direction (the thickness direction of the CMOS image sensor 101) along the gate insulating film on the side face. The drain unit 31 includes a first overflow drain layer 31a containing N-type impurities at a lower concentration than the N-type impurity concentration in the N-type impurity region 9, a second overflow drain layer 31b containing N-type impurities at a lower concentration than in the first overflow drain layer 31a, and a third overflow drain layer 31c containing N-type impurities at nearly the same concentration as in the first overflow drain layer 31a.

These three overflow drain layers result from the manufacturing method described below. In order that the whole of these layers functions as an overflow drain unit, the N-type impurity concentration of each overflow drain layer, particularly the first overflow drain layer 31a, needs to be lower than the N-type impurity concentration in the N-type impurity region 9.

In the first embodiment described above, when the amount of light (mainly in the visible wavelength band) incident on the photodiode 10, which is composed of the P-type epitaxial layer 5 and the N-type impurity region 9, is more than the allowable level for the photodiode 10, excess electrons are produced by photoelectric conversion. The excess electrons flow into the adjacent pixels and the like and will be detected as noise.

In contrast, in the present embodiment, an overflow drain unit 31 is provided as described above. Hence excess electrons produced by light (mainly in the visible wavelength band) incident on the N-type impurity region 9 of the photodiode 10 in an amount more than the allowable level travel through the overflow drain unit 31, the drain portion of the reset transistor 22 (not shown), and the drain line and are ejected outside the semiconductor substrate 2. This can prevent the excess electrons from flowing into the adjacent pixels and causing noise.

Furthermore, in this embodiment, the above-described P⁺-type impurity layer 32 is provided as shown in FIG. 11. Thus, in the N-type impurity region 9 connected to the transfer transistor 8, charge accumulation due to the potential decrease in the N-type impurity region 9 is prevented. This can prevent the above-described excess electrons from flowing back into the photodiode 10 and causing noise when the transfer transistor 8 is reset.

The first overflow drain layer 31a in the overflow drain unit 31 preferably has an N-type impurity concentration about an order of magnitude lower than that of the N-type impurity region 9, and specifically, can be 5×10¹⁵ cm⁻³ to 1×10¹⁶ cm⁻³. The second overflow drain layer 31b preferably has an N-type impurity concentration about an order of magnitude higher than that of the N-type impurity region 9, and specifically, can be 1×10¹⁷ cm⁻³ to 5×10¹⁷ cm⁻³. The N-type impurity region 9 preferably has an N-type impurity concentration of 5×10¹⁶ cm⁻³ to 1×10¹⁷ cm⁻³.

On the frontside of the semiconductor substrate 2, a color filter 15 is formed. On the color filter 15 is formed a microlens 16, which serves as a lens for focusing light and guiding the light to the photodiode 10.

On the backside of the semiconductor substrate 2 (backside of the P-type Si substrate 3) is formed a signal processing section 20 to which the signal charge transferred to the charge storage region 13 is inputted. As shown in FIG. 4, the signal processing section 20 includes a transfer transistor 21, a reset transistor 22, an amplification transistor 23, a vertical selection transistor 24, a horizontal selection transistor 25, a vertical scan circuit 26, a horizontal scan circuit 27, a CDS circuit (correlated double sampling circuit) 28, read control lines 29 and 30, a reset control line 31, a drain line 32, a vertical signal line 33, a horizontal signal line 34, a vertical selection control line 35, a horizontal selection control line 36, and an amplifier 37.

The transfer transistor 21 and the following elements are not described here because they are the same as those in the first embodiment described above.

The CMOS image sensor 101 of this embodiment can also be operated similarly to the first embodiment described above using the circuit as shown in FIG. 4.

In this embodiment again, because the signal processing section 20 is formed on the backside of the semiconductor substrate 2, light incident on the photodiode 10 formed in the semiconductor substrate 2 suffers no interference from interconnects and the like of the signal processing section 20. Thus, even the light obliquely incident on the photodiode 10 can reach the photodiode 10. As a result, the incidence efficiency of light incident on the photodiode 10 can be improved.

Furthermore, because a charge storage region 13 is formed below the N-type impurity region 9 via the P⁺-type impurity layer 32 and a gate electrode 7 is formed in the semiconductor substrate 2, the signal charge stored in the N-type impurity region 9 can be transferred to the signal processing section 20 by this transfer transistor 8.

Moreover, because the photodiode 10 is formed on the frontside of the semiconductor substrate 2 whereas the signal processing section 20 is formed on the backside of the semiconductor substrate 2, the region of the photodiode 10 in the plane of the CMOS image sensor 101 can be increased. Thus the incidence efficiency of light incident on the photodiode 10 can be further improved. In addition, because the region of the photodiode 10 can be increased (ineffective region can be reduced), the microlens 16 can be omitted on the color filter 15.

Furthermore, as shown in FIG. 9, a channel stopper region 11 is juxtaposed with the gate insulating film 6 in the longitudinal direction (vertically across page) of the trench 2a for device isolation between the pixels P. Thus the region occupied by the trenches 2a that penetrate the semiconductor substrate 2 is reduced to a prescribed volume. Therefore the mechanical strength of the semiconductor substrate 2 can be prevented from decreasing.

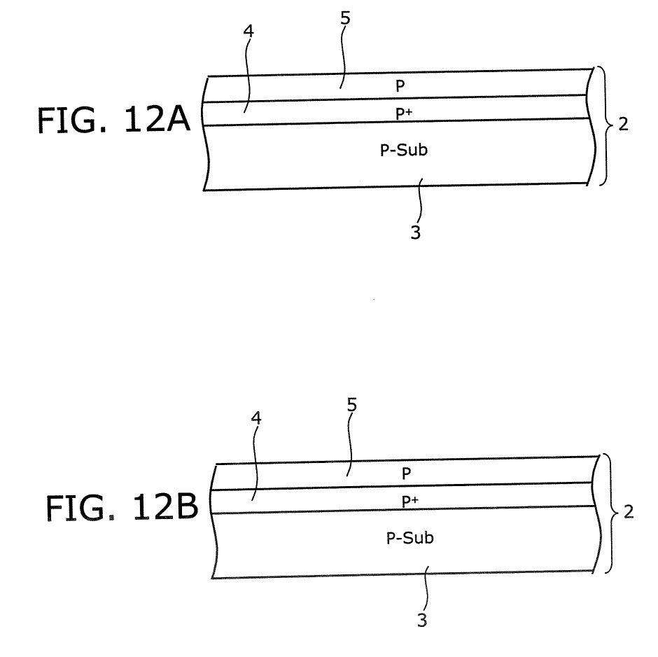

The CMOS image sensor 101 in this embodiment can be fabricated in the following manner. FIGS. 12A to 21B schematically show a process of manufacturing a CMOS image sensor 101 in this embodiment. The figures named with the letter “A” are vertical cross sections along the line A-A of the CMOS image sensor 101, corresponding to FIG. 10 described above. The figures named with the letter “B” are vertical cross sections along the line B-B of the CMOS image sensor 101, corresponding to FIG. 11 described above.

First, as shown in FIGS. 12A and 12B, on a P-type Si substrate 3 having a thickness of several hundreds of micrometers, a P⁺-type epitaxial layer 4 is formed, and then a P-type epitaxial layer 5 is formed. Thus a semiconductor substrate 2 is formed.

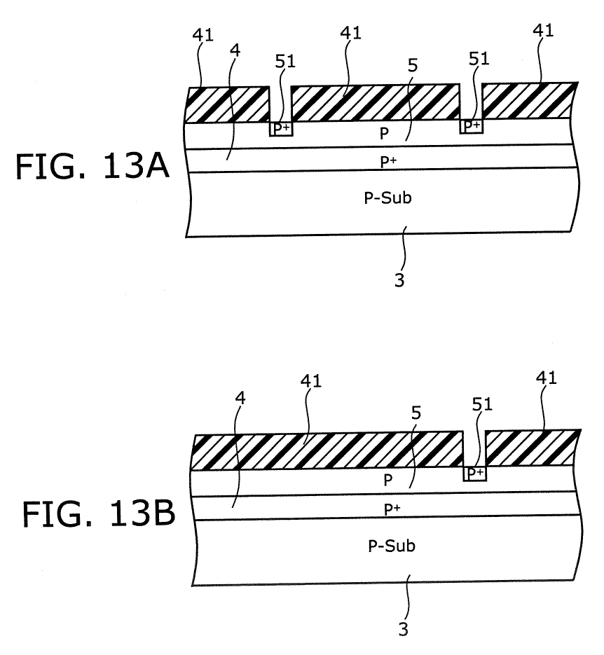

Next, as shown in FIGS. 13A and 13B, a resist pattern 41 is formed by photolithography. Then the resist pattern 41 is used as a mask to inject P-type impurities such as boron into the P-type epitaxial layer 5 by ion implantation, thereby forming a P⁺-type impurity region 51.

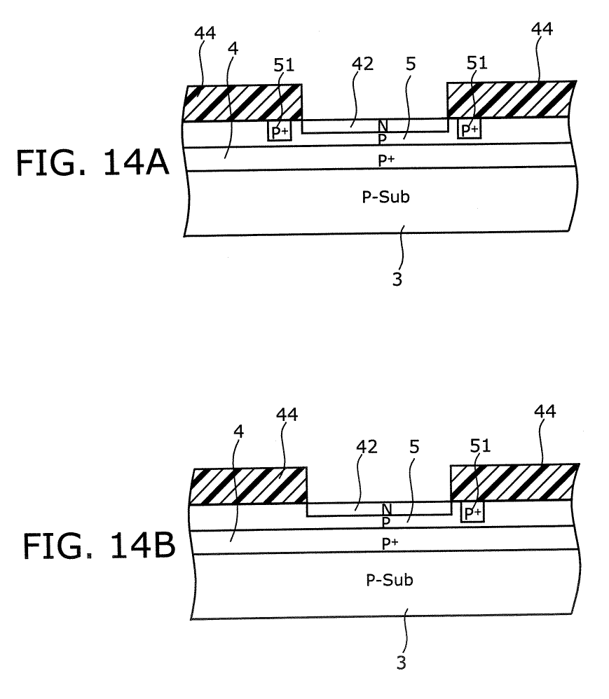

Next, as shown in FIGS. 14A and 14B, after the resist pattern 41 is removed, another resist pattern 44 is used as a mask to inject N-type impurities such as phosphorus or arsenic into the P-type epitaxial layer 5 by ion implantation, thereby forming an N-type impurity region 42, which is to be an N-type impurity region 9 later.

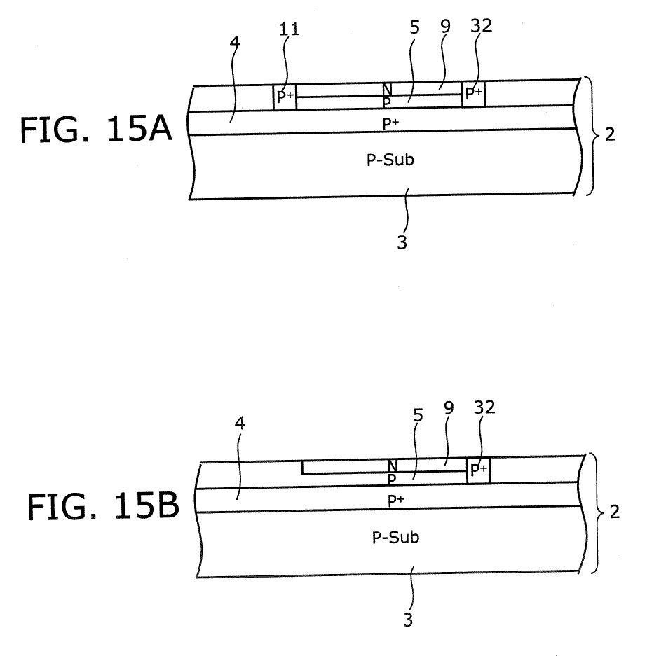

Next, the resist pattern 44 is removed. Then, as shown in FIGS. 15A and 15B, by annealing, N-type impurities constituting the N-type impurity region 42 are diffused, and P-type impurities constituting the P⁺-type impurity region 51 are diffused. Thus an N-type impurity region 9, a channel stopper region 11, and a P⁺-type impurity region 32 are formed.

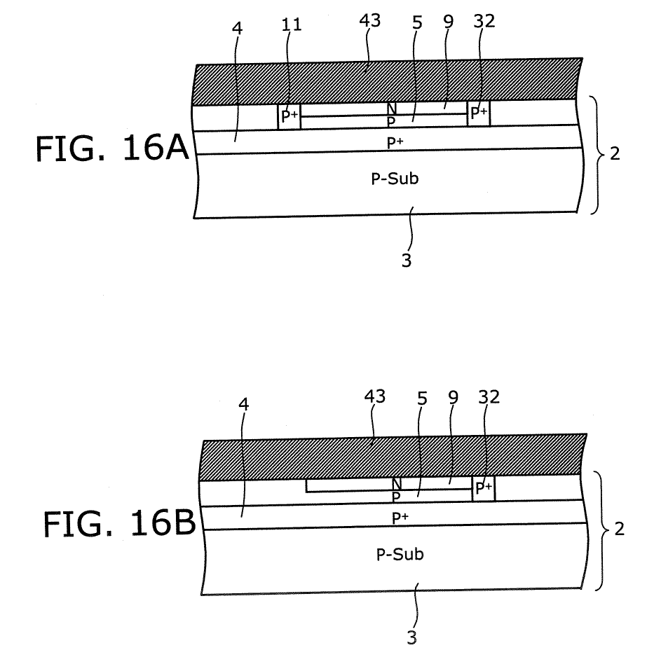

Next, as shown in FIGS. 16A and 16B, an SiO₂ film 43 having a thickness of about 3 μm is formed on the N-type impurity region 9, the channel stopper region 11, and the P⁺-type impurity region 32. Then, the backside of the P-type Si substrate 3 is polished so that the semiconductor substrate 2 has a thickness of about 100 μm. Alternatively, a thin P-type Si substrate 3 may be prepared so that the semiconductor substrate 2 has a thickness of about 100 μm, and a P⁺-type epitaxial layer 4 and a P-type epitaxial layer 5 may be formed on the P-type Si substrate 3. This can save time and effort to polish the backside of the P-type Si substrate 3.

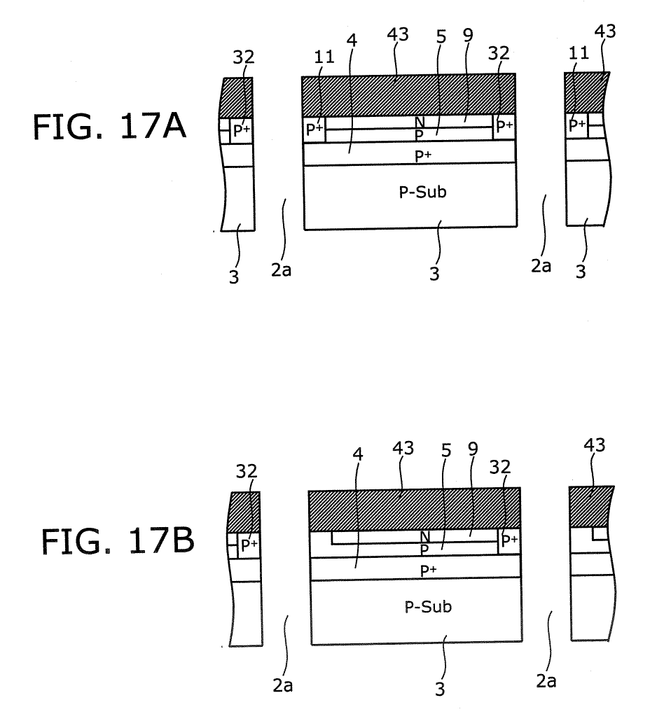

After the backside of the P-type Si substrate 3 is polished, a resist pattern (not shown) is formed on the SiO₂ film 43 by photolithography. Then the resist pattern is used as a mask to etch the SiO₂ film 43 by reactive ion etching (RIE). Then the resist pattern is removed. Next, as shown in FIGS. 17A and 17B, the patterned SiO₂ film 43 is used as a mask to etch the semiconductor substrate 2 in the thickness direction by reactive ion etching or wet etching, thereby forming trenches 2a. Here, etching is conducted so as to penetrate the P-type Si substrate 3, and the trenches 2a are formed as through-holes.

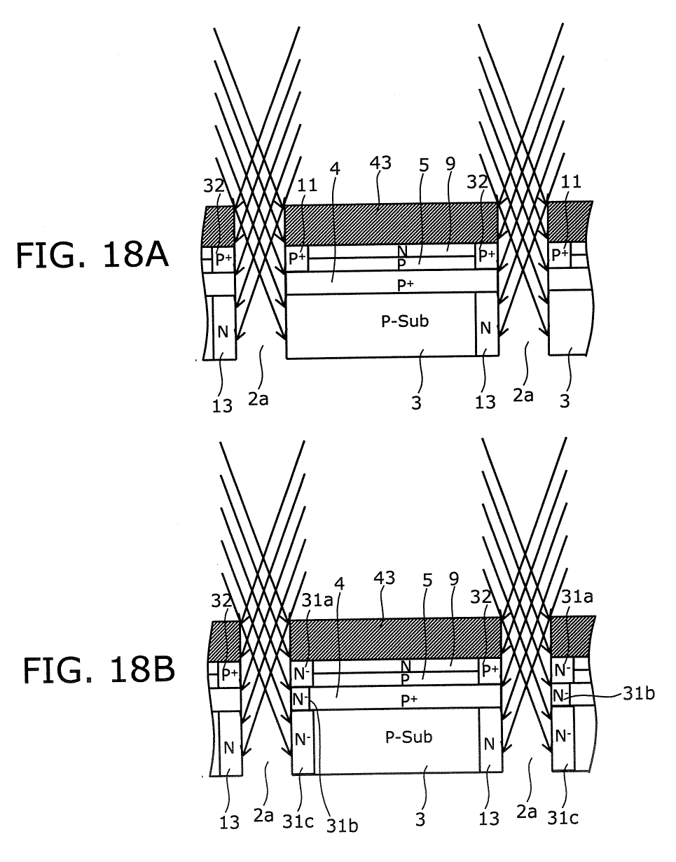

Next, as shown in FIGS. 18A and 18B, N-type impurities are injected into an inner wall on one side of the trench 2a by oblique ion implantation to form a charge storage region 13. N-type impurities are also injected into prescribed regions on the other side of the trench 2a to form a first overflow drain layer 31a, a second overflow drain layer 31b, and a third overflow drain layer 31c. These overflow drain layers will be an N⁻-type impurity region, an N⁻⁻-type impurity region, and an N⁻-type impurity region, respectively, depending on the P-type impurity concentration of the underlying layers.

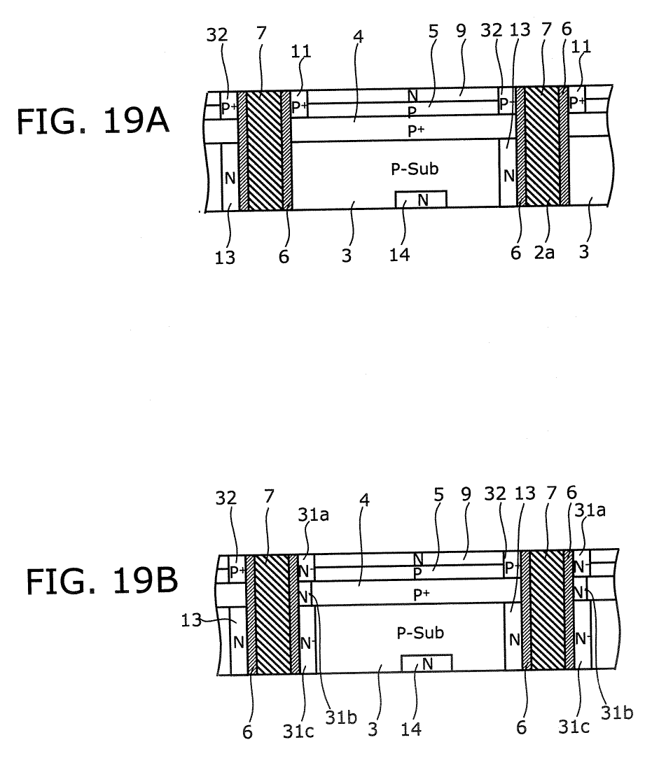

Next, the inner wall of the trench 2a is thermally oxidized to form a gate insulating film 6 as shown in FIGS. 19A and 19B. Subsequently, a conductive material such as poly-Si is buried inside the gate insulating film 6 to form a gate electrode 7. After the gate electrode 7 is formed, the frontside and backside of the semiconductor substrate 2 are polished by chemical mechanical polishing (CMP). In this process, the SiO₂ film 43 is removed.

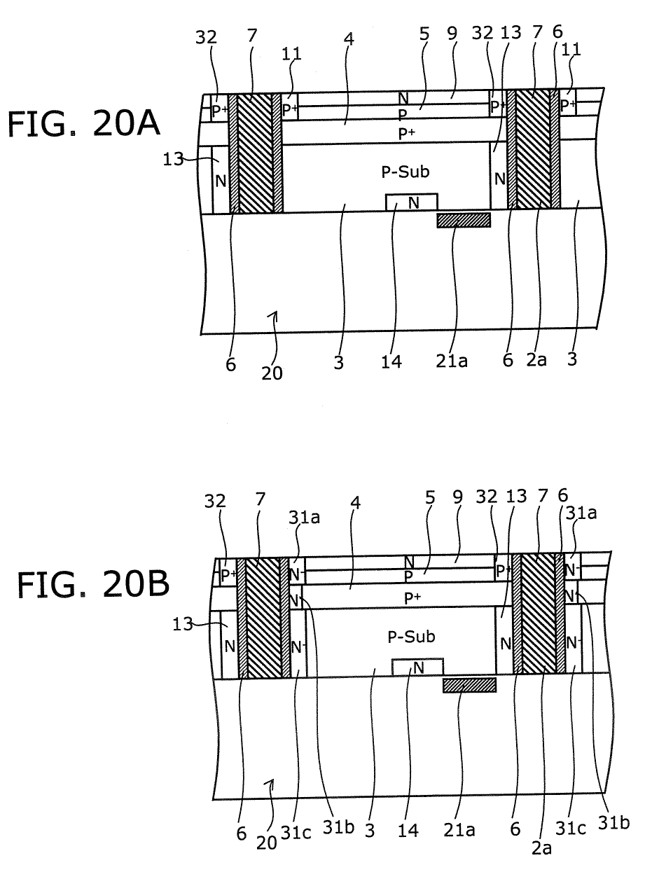

Next, a resist pattern (not shown) is formed on the backside of the semiconductor substrate 2 by photolithography. The resist pattern is used as a mask to inject N-type impurities into the bottom of the P-type Si substrate 3 by ion implantation, thereby forming an FD region 14 at the bottom of the P-type Si substrate 3 as shown in FIGS. 20A and 20B. Subsequently, N-type impurities constituting the FD region 14 are diffused by annealing. Furthermore, a signal processing section 20 is formed on the backside of the P-type Si substrate 3.

In view of efficiency, it is preferable that the gate electrode 21a be formed from the same material (e.g., aluminum) and in the same process as the interconnect pad formed in the signal processing section 20. However, the gate electrode 21a may be formed by using poly-Si in a separate process from that for the interconnect pad.

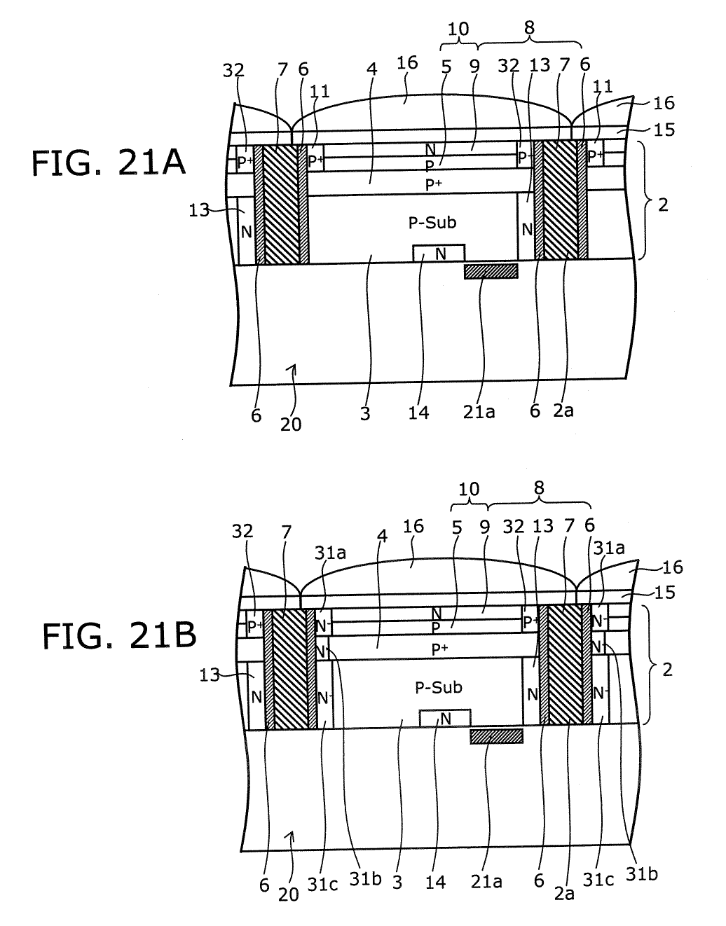

Next, as shown in FIGS. 21A and 21B, a color filter 15 is formed on the N-type impurity region 9 by photolithography, and a microlens 16 is formed on the color filter 15. Thus the CMOS image sensor 101 shown in FIGS. 9 to 11 is fabricated.

The invention has been described in detail with reference to the examples. However, the invention is not limited to the foregoing description, but can be varied or modified without departing from the scope of the invention.

1. A solid-state imaging device comprising:
a semiconductor substrate having;
a first impurity region of a first conductivity type, the first impurity region storing a signal charge produced through photoelectric conversion by a photoelectric conversion section formed in a surface portion of the semiconductor substrate;
a second impurity region of the first conductivity type formed below the first impurity region; and
a first gate electrode penetrating the semiconductor substrate in a thickness direction of the semiconductor substrate, the first gate electrode transferring the signal charge stored in the first impurity region to the second impurity region; and
a signal processing section provided on a backside of the semiconductor substrate, the signal processing section receiving the signal charge transferred to the second impurity region.

2. A solid-state imaging device according to claim 1, wherein the semiconductor substrate further has a third impurity region of a second conductivity type provided below the first impurity region.

3. A solid-state imaging device according to claim 2, wherein the semiconductor substrate further has a fourth impurity region of the second conductivity type provided between the second impurity region and the third impurity region, the fourth impurity region having impurities at a higher concentration than the impurity concentration in the third impurity region.

4. A solid-state imaging device according to claim 3, wherein the semiconductor substrate further has a fifth impurity region of a second conductivity type provided below the fourth impurity region and adjoining the second impurity region.

5. A solid-state imaging device according to claim 4, wherein
the fifth impurity region reaches the backside of the semiconductor substrate, and
the semiconductor substrate further has a sixth impurity region of the first conductivity type provided in the fifth impurity region on the backside of the semiconductor substrate.

6. A solid-state imaging device according to claim 5, wherein the signal processing section has a second gate electrode transferring the signal charge from the second impurity region to the sixth impurity region.

7. A solid-state imaging device according to claim 1, wherein the semiconductor substrate further has a seventh impurity region of the second conductivity type extending along a first direction, the first direction being parallel to a major surface of the semiconductor substrate, the seventh impurity region dividing the first impurity region into pixels.

8. A solid-state imaging device according to claim 7, wherein the semiconductor substrate further has an eighth impurity region of the second conductivity type provided between the seventh impurity region and the first gate electrode.

9. A solid-state imaging device comprising:
a semiconductor substrate having;
a first impurity region of a first conductivity type, the first impurity region storing a signal charge produced through photoelectric conversion by a photoelectric conversion section formed in a surface portion of the semiconductor substrate;
a second impurity region of the first conductivity type formed in the semiconductor substrate at a part lower than the first impurity region;
a first gate electrode penetrating the semiconductor substrate in a thickness direction of the semiconductor substrate, the first gate electrode transferring the signal charge stored in the first impurity region to the second impurity region; and
an overflow drain unit of the first conductivity type being in contact with the first impurity region, the overflow drain unit extending to a backside of the semiconductor substrate; and
a signal processing section provided on the backside of the semiconductor substrate, the signal processing section receiving the signal charge transferred to the second impurity region.

10. A solid-state imaging device according to claim 9, wherein the overflow drain unit includes an overflow drain layer having impurities at a lower concentration than the impurity concentration in the first impurity region.

11. A solid-state imaging device according to claim 9, wherein the semiconductor substrate further has a third impurity region of a second conductivity type provided below the first impurity region.

12. A solid-state imaging device according to claim 11, wherein the semiconductor substrate further has a fourth impurity region of the second conductivity type provided between the second impurity region and the third impurity region, the fourth impurity region having impurities at a higher concentration than the impurity concentration in the third impurity region.

13. A solid-state imaging device according to claim 12, wherein the semiconductor substrate further has a fifth impurity region of a second conductivity type provided below the fourth impurity region and adjoining the second impurity region.

14. A solid-state imaging device according to claim 13, wherein
the fifth impurity region reaches the backside of the semiconductor substrate, and
the semiconductor substrate further has a sixth impurity region of the first conductivity type provided in the fifth impurity region on the backside of the semiconductor substrate.

15. A solid-state imaging device according to claim 14, wherein the signal processing section has a second gate electrode transferring the signal charge from the second impurity region to the sixth impurity region.

16. A solid-state imaging device according to claim 9, wherein the semiconductor substrate further has a seventh impurity region of the second conductivity type extending along a first direction, the first direction being parallel to a major surface of the semiconductor substrate, the seventh impurity region dividing the first impurity region into pixels.

17. A solid-state imaging device according to claim 16, wherein the semiconductor substrate further has an eighth impurity region of the second conductivity type provided between the seventh impurity region and the first gate electrode.

18. A method of manufacturing a solid-state imaging device, comprising:
forming a first impurity region of a first conductivity type, the first impurity region stroring a signal charge produced through photoelectric conversion by a photoelectric conversion section in a surface portion of a semiconductor substrate;
forming a trench, the trench penetrating the semiconductor substrate;
forming a second impurity region of the first conductivity type at a part lower than the first impurity region in the semiconductor substrate by introducing impurities of the first conductivity type on at least one side face of an inner wall of the trench;
forming a gate electrode by burying a conductive material in the trench via an insulating film; and
forming a signal processing section on the backside of the semiconductor substrate.

19. A method of manufacturing a solid-state imaging device according to claim 18, further comprising:
forming an overflow drain unit of the first conductivity type being in contact with the first impurity region and extending to a backside of the semiconductor substrate by introducing impurities of the first conductivity type on the other side face of the inner wall of the trench.

20. A method of manufacturing a solid-state imaging device according to claim 18, wherein the first impurity region is formed selectively in a surface portion of a third impurity region of a second conductivity type.
